(19) United States
(12) Patent Application Publication
(10) Pub. No.: US 2014/0170848 A1
(43) Pub. Date: Jun. 19, 2014

(54) Method of Forming Substrate

(71) Applicant: Viking Tech Corporation, Hsinchu County (TW)

(72) Inventors: Shih-Long Wei, Hsinchu County (TW); Shen-Li Hsiao, Hsinchu County (TW); Chien-Hung Ho, Hsinchu County (TW)

(73) Assignee: Viking Tech Corporation, Hsinchu County (TW)

(21) Appl. No.: 14/105,344

(22) Filed: Dec. 13, 2013

(30) Foreign Application Priority Data
Dec. 13, 2012 (TW) 101147108

(51) Int. Cl. H01L 33/62

(52) U.S. Cl. CPC H01L 33/62
USPC 438/612

(57) ABSTRACT

A method of forming a substrate is provided, which includes steps of providing a metal plate having a first surface and a second surface; forming a plurality of recesses on the first surface of the metal plate by using laser cutting technique; filling the plurality of recesses with an insulating material; removing a part of the metal plate in a direction of from the second surface to the first surface, so that two ends of the insulating material are exposed, and a substrate body is formed by a conductor portion formed by the remaining part of the metal plate and an insulating portion formed by the insulating material; and forming a circuit layer on a first surface of the substrate body and a circuit layer on a second surface of the substrate body is provided. Thus, the two circuit layers are electrically connected by the conductor portion that also provides a heat dissipation path and are separated by the insulating portion.

### BACKGROUND OF THE INVENTION

This invention relates to a method of forming a substrate, and more particularly, to a method of forming a substrate for carrying a light-emitting diode.

### DESCRIPTION OF RELATED ART

Although electronic products are gradually becoming compact in size, in order to provide a better durability, the keys of research and development must comprise how to provide a higher efficiency for heat dissipation in electronic products.

Currently used substrates for providing the arrangement of light-emitting diodes comprise ceramic substrates, wherein two circuit layers are formed on two surfaces of the ceramic substrate and a plurality of conductive vias pass through the ceramic substrate for electrically connecting the two circuit layers. A light-emitting diode is disposed on the circuit layer, such that the heat produced from the operation of the light-emitting diode can be dissipated by the ceramic substrate.

However, the thermal conductivity coefficient of a ceramic material is far smaller than that of a general aluminum or copper material, and thus the heat conduction and dissipation effects of a substrate formed by a ceramic material are usually not ideal. Although conductive vias can also provide a certain extent of heat dissipation effect, the heat dissipation efficiency for the entire substrate still relies on the ceramic material since the volume of the conductive vias is far smaller than that of the portion formed by the ceramic material in the substrate.

Hence, there is a need to improve the heat dissipation efficiency of a substrate.

### SUMMARY OF THE INVENTION

In view of the above-mentioned problems of the prior art, the present disclosure provides a method of forming a substrate having an ideal heat dissipation effect.

In one aspect of the present disclosure, a method of forming a substrate that comprises the following steps is provided: providing a metal plate having a first surface and a second surface; forming a plurality of recesses on the first surface of the metal plate by using laser cutting technique; filling the plurality of recesses with an insulating material; removing a part of the metal plate in a direction of from the second surface to the first surface, so that two ends of the insulating material are exposed, and a substrate body is formed by a conductor portion provided by the remaining part of the metal plate and an insulating portion provided by the insulating material; and forming a first circuit layer on a first surface of the substrate body and a second circuit layer on a second surface of the substrate body, wherein the two circuit layers are electrically connected by the conductor portion which also provides a thermally conductive effect, and wherein the circuit layer is internally separated by the insulating portion.

In another aspect of the present disclosure a method of forming a substrate that comprises the following steps is provided: providing an insulating plate having a first surface and a second surface; forming a plurality of hollow regions in the insulating plate from the first surface to the second surface by using laser cutting technique; filling the plurality of hollow regions with a metal material to form a substrate body having a first surface and a second surface, wherein the substrate body is formed by a conductor portion provided by the metal material and an insulating portion provided by the insulating plate; and forming a first circuit layer on a first surface of the substrate body and a second circuit layer on a second surface of the substrate body, wherein the first and second circuit layers are electrically connected by the conductor portion which also provides a thermally conductive effect, and wherein the circuit layer is internally separated by the insulating portion.

It can be seen that the present disclosure uses a conductor portion having large volume as the main material of the substrate, and thus the connection between circuit layers is built and a better heat dissipation function for the entire substrate is provided because of its good heat conductivity. The drawbacks derived from the low thermal conductivity coefficient of a conventional ceramic substrate can be avoided.

### BRIEF DESCRIPTION OF DRAWINGS

The invention can be more fully understood by reading the following detailed description of the preferred embodiments, with reference made to the accompanying drawings, wherein:

FIGS. 1A, 1A′, 1B, 1C, 1D and 1E are used to illustrate the first embodiment of the method of forming a substrate in the present invention; and

FIGS. 2A, 2B, 2B′ and 2C are used to illustrate the second embodiment of the method of forming a substrate in the present invention.

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

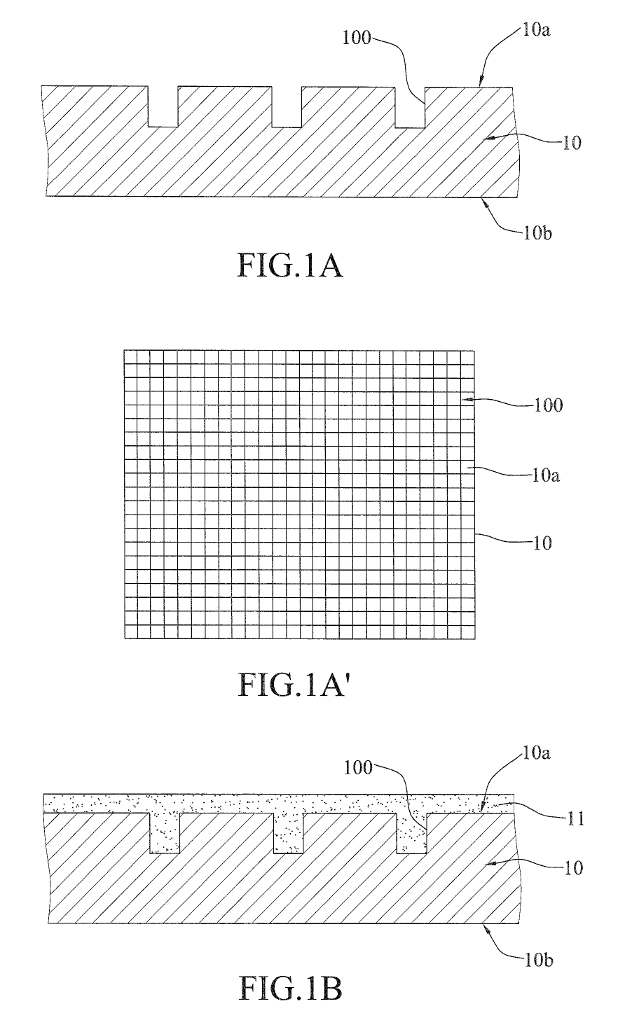

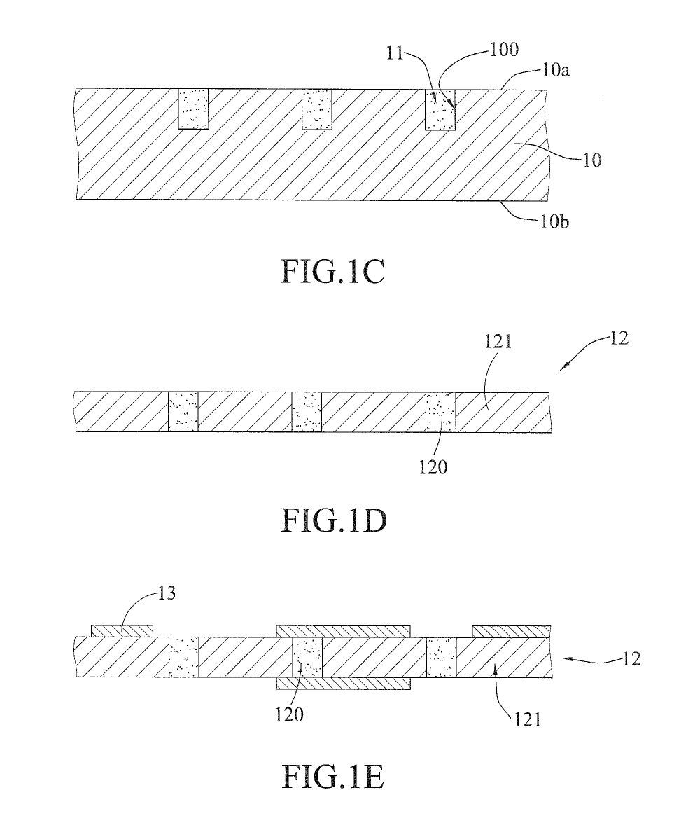

Please refer to FIGS. 1A-1E, the first embodiment of the method of forming a substrate is provided.

In the first embodiment of the method of forming a substrate, as shown in FIGS. 1A, 1B and 1C, a metal plate 10 having a first surface 10a and a second surface 10b was provided. Then, a plurality of recesses 100 were formed on the first surface 10a by using laser cutting technique, and each of the plurality of recesses 100 was filled with an insulating material 11.

In this embodiment, a metal plate 10 formed by such as a copper or aluminum material was provided. Secondly, as shown in the schematic top view of FIG. 1A′, a plurality of staggered recesses 100 was formed on the first surface 10a by using laser cutting technique, and those staggered recesses 100 could form a staggered arrangement with a high density on the first surface 10a.

Furthermore, in this embodiment, each of the recesses 100 was filled with an insulating material 11, such as a polymeric or ceramic material. Specifically, for the step of filling the insulating material 11, the insulating material 11 could be uniformly formed on the first surface 10a and in the recesses 100, as shown in FIG. 1B. Next, the insulating material 11 above the first surface 10a was removed, and only the insulating material 11 in the recess 100 was left, as shown in FIG. 1C.

Furthermore, in this embodiment, a part of the metal plate 10 was removed in a direction of from the second surface 10b to the first surface 10a, so that two ends of the insulating material 11 in the recess 100 were exposed, and a substrate body 12 having two surfaces was formed, as shown in FIG. 1D. That is, the substrate body 12 was formed by a conductor portion 121 provided by the remaining part of the metal plate 10 (which had not been removed yet) and an insulating portion 120 provided by the insulating material 11. In this embodiment, when forming the insulating portion 120 and the conductor portion 121, the conductor portion 121 had larger volume than the insulating portion 120.

Subsequently, the circuit layers 13 were formed on two surfaces of the substrate body 12, such that the two circuit layers 13 were electrically connected by the conductor portion 121, and the produced heat could be dispelled through the conductor portion 121, so as to achieve the heat dissipation effect. In addition, the two circuit layers 13 were separated by the insulating portion 120, so as to avoid short circuits in each circuit layer 13.

In this embodiment, the circuit layers 13 was bonding pads for connecting to a light-emitting diode. In other words, when the light-emitting diode was conducted to emit, an excellent heat dissipation effect could be provided by the metal property of the conductor portion 121 with large volume. Since the technique for arranging light-emitting diodes is conventional, a detailed description will not be provided herein.

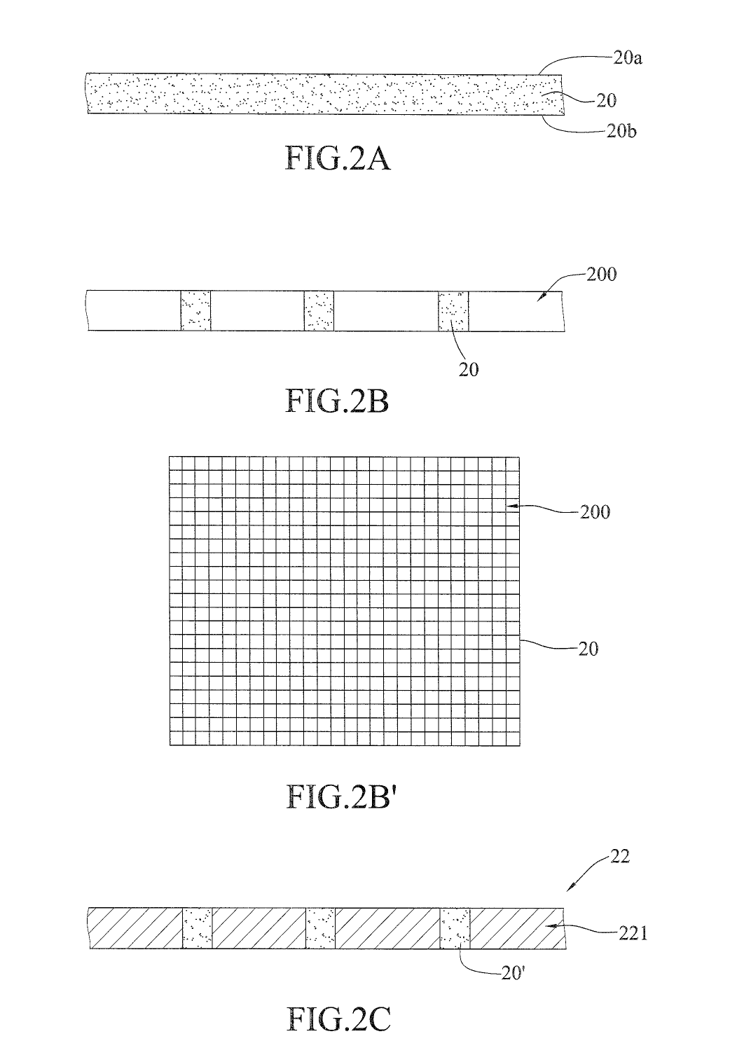

In addition, referring to FIGS. 2A-2C, the second embodiment of the method of forming a substrate is provided.

In the second embodiment of the method of forming a substrate, an insulating plate 20 having a first surface 20a and a second surface 20b was provided. In this embodiment, the insulating plate 20 could be formed by such as a polymeric or ceramic material.

In this embodiment, a plurality of hollow regions 200 passing through the insulating plate 20 from the first surface 20a to the second surface 20b were formed by using laser cutting technique, as shown in FIG. 2B.

In this embodiment, the plurality of hollow regions 200 formed from the first surface 20a to the second surface 20b were staggered as shown in the schematic top view of FIG. 2B′, such as being staggered in a format of a high density.

Furthermore, the plurality of hollow regions 200 were filled with a metal material 221 to form a substrate body 22 having two surfaces. That is, the substrate body 22 was formed by a conductor portion provided by the metal material 221 (i.e. the metal material 221 shown by stripes) and the insulating portion 20′ provided by the insulating plate 20 (i.e. the region represented by dots), as shown in FIG. 2C.

In this embodiment, the plurality of hollow regions 200 as shown in FIG. 2B could be filled with the metal material 221, such as a copper or aluminum material, and thus the conductor portion (where the metal material 221 is) having larger volume than that of the insulating portion 20′ was formed.

Subsequently, circuit layers (which is not shown, but the circuit layer 13 shown in FIG. 1E can be referred to) were formed on two surfaces of the substrate body 22, such that the two circuit layers were electrically connected by the conductor portion (which also provided the heat dissipation effect) and were separated by the insulating portion 20′. In this embodiment, the circuit layer was bonding pads for connecting to a light-emitting diode.

As described above, the present disclosure can provide a conductor portion having relatively larger volume as the main material of the substrate, thereby building an electrical connection between the conductor portion and circuit layer and providing a better heat dissipation effect for the substrate during the subsequent entire operation because the conductor portion having relatively larger volume has good heat conductivity. Thus, the defects derived from the low thermal conductivity coefficient of a conventional ceramic substrate can be avoided.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A method of forming a substrate, comprising:
providing a metal plate having a first surface and a second surface;
forming a plurality of recesses on the first surface of the metal plate by using laser cutting technique;
filling the plurality of recesses with an insulating material;
removing a part of the metal plate in a direction of from the second surface to the first surface, so that two ends of the insulating material are exposed, and a substrate body is formed by a conductor portion formed by a remaining part of the metal plate and an insulating portion formed by the insulating material; and
forming a first circuit layer on a first surface of the substrate body and a second circuit layer on a second surface of the substrate body,
wherein the first and second circuit layers are electrically connected by the conductor portion and are separated by the insulating portion.

2. The method of claim 1, wherein the metal plate is formed by a copper or aluminum material.

3. The method claim 1, wherein the plurality of recesses are staggered, and the insulating material is a polymeric or ceramic material.

4. The method of claim 1, wherein the conductor portion has larger volume than the insulating portion.

5. The method of claim 1, wherein the first or second circuit layer is bonding pads for connecting to a light-emitting diode.

6. A method of forming a substrate, comprising:
providing an insulating plate having a first surface and a second surface;
forming a plurality of hollow regions in the insulating plate from the first surface to the second surface by using laser cutting technique;
filling the plurality of hollow regions with a metal material to form a substrate body having a first surface and a second surface, wherein the substrate body is formed by a conductor portion formed by the metal material and an insulating portion formed by the insulating plate; and
forming a first circuit layer on a first surface of the substrate body and a second circuit layer on a second surface of the substrate body, wherein the first and second circuit layers are electrically connected by the conductor portion and are separated by the insulating portion.

7. The method of claim 6, wherein the insulating plate is formed by a polymeric material or ceramic material.

8. The method of claim 6, wherein the plurality of hollow regions are staggered.

9. The method of claim 6, wherein the metal material is a copper or aluminum material, and the conductor portion has larger volume than the insulating portion.

10. The method of claim 6, wherein the first or second circuit layer is bonding pads for connecting to a light-emitting diode.
